(19) United States
(12) Patent Application Publication
(10) Pub. No.: US 2026/0230044 A1
(43) Pub. Date: Aug. 6, 2026

(54) ELECTRICAL BIASING CIRCUIT WITH CURRENT LIMITER

(71) Applicant: GlobalFoundries U.S. Inc., Malta, NY (US)

(72) Inventors: Vasudeva Reddy Kuppireddy, Bangalore (IN); Venkata Narayana Rao Vanukuru, Bangalore (IN)

(21) Appl. No.: 19/046,788

(22) Filed: Feb. 6, 2025

(51) Int. Cl. H03F 1/52; H03F 3/45

(52) U.S. Cl. CPC H03F 1/52; H03F 3/45475; H03F 2200/294

(57) ABSTRACT

The disclosure provides an electrical biasing circuit with a current limiter, e.g., for biasing of amplifiers. A structure of the disclosure includes an operational transconductance amplifier (OTA). The OTA includes first input terminal connected to a reference signal output node to receive a reference voltage, a second input terminal connected to a bias signal output node to receive a bias voltage, and an output terminal. A first transistor is connected between a positive supply voltage rail and the bias signal output node. The first control terminal of the first transistor is connected to the output terminal of the OTA.

### BACKGROUND

The present disclosure relates to electrical biasing circuits and, more particularly, to embodiments of an electrical biasing circuit with a current limiter.

Low noise amplifiers (LNAs) are important for use in a variety of different applications, for example, radio frequency (RF) technology applications as well as other technical fields such as in satellite-based applications (global positioning systems (GPSs) and global navigation satellite systems (GNSs)). LNAs rely upon electrical biasing circuits to operate. Notably, characteristics of the biasing circuit will affect the amount of noise added to the amplified signal and/or the linearity (i.e., how proportionate the output is to its corresponding input) of the amplified signal. Although a variety of biasing circuits are available for implementation with LNAs, these circuits may have technical drawbacks unsuitable for certain applications. For example, some biasing circuits require higher supply voltages than may be available for low power or ultra-low power devices. Other biasing circuits may rely on lower supply voltages but include multiple current pathways (e.g., causing leakage) or resistors (e.g., reducing linearity), either of which will negatively affect the effectiveness of the LNA circuit.

### SUMMARY

Embodiments of the disclosure provide a structure including: an operational transconductance amplifier (OTA) including: a first input terminal connected to a reference signal output node to receive a reference voltage, and a second input terminal connected to a bias signal output node to receive a bias voltage; and an output terminal; and a first transistor connected between a positive supply voltage rail and the bias signal output node, wherein a first control terminal of the first transistor is connected to the output terminal of the OTA.

Further embodiments of the disclosure provide a structure including: an operational transconductance amplifier (OTA) including: a first input terminal connected to a reference signal output node to receive a reference voltage, and a second input terminal connected to a bias signal output node to receive a bias voltage; and an output terminal; a first transistor connected between a positive supply voltage rail and the bias signal output node, wherein a first control terminal of the first transistor is connected to the output terminal of the OTA, and the bias signal output node is connected to an input signal; a reference current source and a second transistor connected in series between the positive supply voltage rail and ground, wherein the reference signal output node is at a junction between the reference current source and the second transistor; and a low noise amplifier (LNA) coupled to the bias signal output node.

Additional embodiments of the disclosure provide a method including: transmitting a reference voltage to a structure including: an operational transconductance amplifier (OTA) including: a first input terminal connected to a reference signal output node to receive the reference voltage, and a second input terminal connected to a bias signal output node to receive a bias voltage; and an output terminal, and a first transistor connected between a positive supply voltage rail and the bias signal output node, wherein a first control terminal of the first transistor is connected to the output terminal of the OTA; and electrically biasing a load coupled to the bias signal output node with the bias voltage.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIGS. 1a, 1b, and 1c depict various conventional low noise amplifier (LNA) circuits.

FIG. 2 depicts a schematic diagram of a structure according to embodiments of the disclosure.

FIG. 3 depicts a schematic diagram of an equivalent circuit for the structure shown in FIG. 2, according to embodiments of the disclosure.

FIG. 4 depicts a cross-sectional view of multiple integrated circuit (IC) modules, one IC module having a structure according to embodiments of the disclosure.

FIG. 5 depicts an illustrative flow diagram for implementing a method according to embodiments of the disclosure.

### DETAILED DESCRIPTION

As mentioned above, LNAs are important for use in a variety of different applications, for example, radio frequency (RF) technology applications as well as other technical fields such as in satellite-based applications (global positioning systems (GPSs) and global navigation satellite systems (GNSs)). LNAs rely upon electrical biasing circuits to operate, and characteristics of the biasing circuit will affect the amount of noise added to the amplified signal and/or the linearity (i.e., how proportionate the output is to its corresponding input) of the amplified signal. Although a variety of biasing circuits are available for implementation with LNAs, these circuits may have technical drawbacks unsuitable for certain applications. For example, some biasing circuits require higher supply voltages than may be available for low power or ultra-low power devices. Other biasing circuits may rely on lower supply voltages but include multiple current pathways (e.g., causing leakage) or resistors (e.g., reducing linearity), either of which will negatively affect the effectiveness of the LNA circuit.

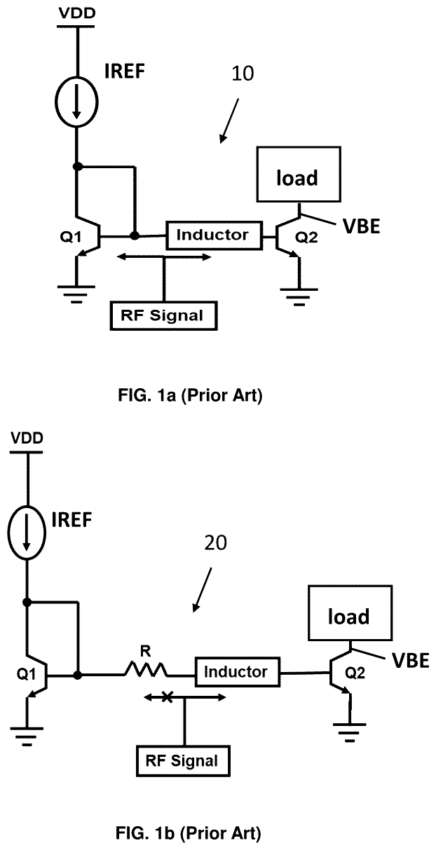

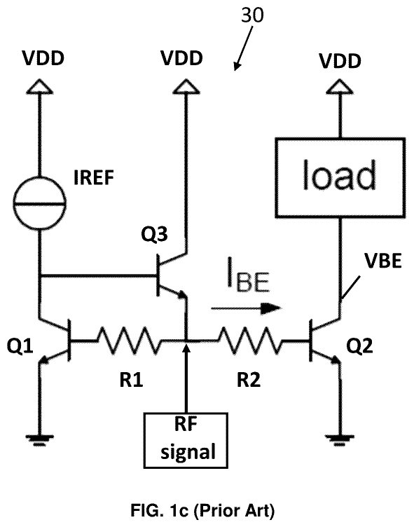

FIGS. 1a, 1b, and 1c provide examples of conventional biasing circuits for an LNA and illustrate some of the above-noted technical drawbacks. In a conventional biasing circuit 10, an incoming radio frequency (RF) signal enters the biasing circuit at the junction between a current mirror (including a reference current generator IREF coupled to a positive voltage supply rail VDD, and a diode-connected bipolar transistor Q1) and a biasing stage including an inductor coupled to the base of a bipolar transistor Q2 connected at its collector to a load (e.g., any LNA circuit to be biased) and at its emitter to ground. Circuit 10 includes a direct electrical connection from the inductor to the base of transistor Q1, and thus, incoming RF signals are able to flow toward the electrical load, or undesirably, toward the current mirror components.

Another conventional biasing circuit 20 (shown in FIG. 1b) attempts to address the issues of FIG. 1a by including a resistor R at the junction between the inductor and the base of bipolar transistor Q1. As shown, resistor R will substantially prevent (or otherwise greatly reduce) the current from incoming RF signals from flowing toward the current mirror side of biasing circuit 20. The addition of resistor R to biasing circuit 20, on the other hand, degrades the linearity of amplified signals amplified in the load connected thereto.

Yet another conventional biasing circuit 30 (shown in FIG. 1c) attempts to mitigate the disadvantages of circuits 10 and 20 by including multiple resistors R1, R2, each coupled to the base of one of bipolar transistors Q1, Q2 on each side of the biasing circuit. A third bipolar transistor Q3 is coupled at its base to IREF, coupled to positive voltage supply rail VDD at its collector, and to the RF signal input at its emitter. The use of resistors R1, R2 and third bipolar transistor Q3 causes conventional biasing circuit 30 to offer better linearity than conventional biasing circuit 20 and also reduces the reference current IREF magnitude needed for biasing. Disadvantageously, conventional biasing circuit 30 requires a much higher voltage supply magnitude. To provide a sufficient biasing voltage (VBE), the positive voltage supply VDD must be equal to twice the desired biasing voltage (2*VBE), added to the voltage magnitude for generating the reference current (VIREF). The various disadvantages of conventional biasing circuits 10, 20, 30 render them unsuitable for biasing LNA circuits in low voltage settings.

In view of the forgoing, disclosed herein are embodiments of an electrical biasing circuit with a current limiter, e.g., for biasing of amplifiers. A structure of the disclosure includes an operational transconductance amplifier (OTA). The OTA includes first input terminal connected to a reference signal output node to receive a reference voltage, a second input terminal connected to a bias signal output node to receive a bias voltage, and an output terminal. A first transistor is connected between a positive supply voltage rail and the bias signal output node. The first control terminal of the first transistor is connected to the output terminal of the OTA.

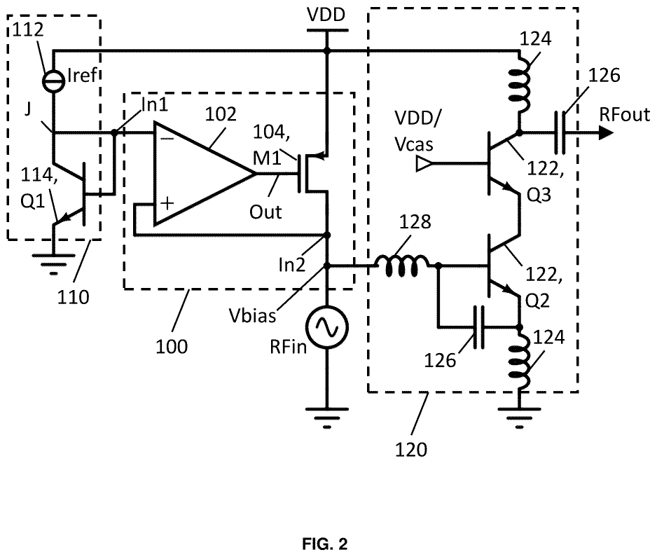

Referring to FIG. 2, a schematic diagram of a structure 100 according to embodiments of the disclosure is shown. Structure 100 may include an operational transimpedance amplifier (OTA) 102 interconnected with a first transistor 104 (also labeled “M1”) for simultaneous limiting of currents transmitted from a current generator 110 to a load 120, and simultaneously, substantially impeding or altogether preventing input signals (e.g., from a radio frequency (RF) signal source RFin) from passing into current generator 110 from structure 100. An OTA is an electrical component derived from a set of interconnected transistors, resistors, and/or other fundamental circuit components according to any currently known or later developed circuit configurations. However implemented, OTA 102 is operable to convert an input current at one of its input terminals into a proportionate output voltage at its output terminal. During operation OTA 102 exhibits the same voltage at its two input terminals and substantially zero current (i.e., only an insubstantial leakage current) into its two input terminals, and thus operates simply as a voltage gain device.

In structure 100, OTA 102 includes a first input terminal In1 connected to a reference signal output node J in current generator 110. Reference signal output node J is the output from a reference current source 112 configured to transmit a reference current (“Iref”) from a positive voltage supply rail (“VDD”). Reference current source 112 may be any currently known or later developed current source for producing a desired amount of current from positive voltage supply rail VDD, e.g., a current mirror or any other currently known or later developed device for providing a desired electric current to first input terminal In1.

OTA 102 in structure 100 also includes a second input terminal In2 connected to a bias signal output node (“Vbias”) to receive (and thus define) a bias voltage for transmission to load 120. Second input terminal In2 may connect to RFin and the source terminal of first transistor 104. First transistor 104 may be in the form of a metal oxide semiconductor field effect transistor (MOSFET) having a predetermined polarity. As shown, first transistor 104 may take the form of a p-type doped FET(“PFET”) , but this is not necessarily required. As discussed elsewhere herein, first transistor 104 may be a different transistor from other transistors in structure 100 and/or components connected thereto. For example, where first transistor 104 is a FET, other transistors in current generator 110 and/or load 120 may be bipolar junction transistors (BJTs).

First transistor 104 is connected at its control terminal (i.e., gate) to the output of OTA 102 (i.e., at terminal “Out”), to second input terminal In2 at its source, and to positive voltage supply rail VDD at its drain. In structure 100, first transistor 104 is connected between positive voltage supply rail VDD and bias signal output node Vbias through second input terminal In2. As noted herein, the output from OTA 102 is proportionate to the current at input terminal In1, i.e., higher amounts of current will create higher voltages at terminal “Out” from OTA 102. Thus, any reference current sufficient to produce an output voltage in excess of the threshold voltage of first transistor 104 will enable source-drain current flow from positive voltage supply rial VDD to bias signal output node Vbias and thus fix its voltage to substantially the magnitude of Vbias, regardless of the magnitude of reference current Iref. OTA 102 and first transistor 104 thus cooperate to provide a “current limiter,” i.e., an electrical component configured to prevent the voltage produced from current generator 110 (and hence the voltage at node Vbias) from exceeding a predetermined magnitude.

Current generator 110 may include a second transistor 114 connected in series between reference current source 112 and ground. Reference signal output node J is at a junction between reference current source 112 and second transistor 114. Second transistor 114 may include a bipolar junction transistor (BJT), e.g., an NPN-type BJT (Q1) having an emitter terminal coupled to ground, and control terminal (“base”) and collector terminals each coupled to reference signal output node J. In this configuration, second transistor 114, Q1 may function as a “diode-connected transistor” enabling current flow in only one direction, i.e., from reference current source 112 and reference signal output node J. Notably, second transistor 114, Q1 may be a different type of transistor and/or may at least include different doping from first transistor 104 (e.g., first transistor 104 may be a FET and second transistor 114 may be a BJT). That is, second transistor 114 and first transistor 104 are different types of transistors. Multiple transistor architectures may be provided, e.g., by implementing each transistor 104, 114 in a different IC module as shown and discussed elsewhere herein. In this configuration, first input terminal In1 may be an inverting input terminal to OTA 102, such that the voltage at output terminal (Out) from OTA 102 has an opposite polarity from the voltage at first input terminal In1. In this case, second input terminal In2 is a non-inverting input terminal and thus has a same voltage polarity as the voltage at output terminal (Out) from OTA 102.

Load 120 can be connected to positive voltage supply rail VDD and bias signal output node Vbias of structure 100. In FIG. 2, load 120 is illustrated as being a low noise amplifier (LNA) circuit, although load 120 may be any electrical load in need of biasing. In the case of an LNA circuit, load 120 may include a set of cascode BJTs 122 (separately labeled Q2, Q3) connected in series from collector to emitter between a pair of amplifier inductors 124. In alternative implementations, cascode BJTs 122 may be FETs and amplifier inductors 124 may be resistors. The term “cascode” refers to an amplifier circuit with multiple interconnected amplifying transistors (e.g., BJTs as shown in FIG. 2), connected at shared nodes to function as a single amplifying device. The output from load 120, in this case, may be connected to the collector of one cascode BJT 122 (e.g., Q3 as shown) through a capacitor 126, and positive voltage supply rail VDD may be coupled to load 120 through one of the serially coupled amplifier inductors 124. The control terminal (e.g., base) of one cascode BJT 122 (e.g., Q3 as shown) may be coupled to an adjustable voltage node alternately tied to positive supply voltage rail VDD or to a control voltage (“Vcas”) for the LNA circuit, e.g., to turn load 120 on or off. Another cascode BJT 122 (e.g., Q2 as shown) may be coupled to biasing node Vbias and to input signal RFin at input node In2 of structure 100 through a biasing inductor 128.

Biasing inductor 128 is coupled to the control node (e.g., base) of cascode BJT 122 (e.g., Q2 as shown) or another transistor. Biasing inductor 128 may be coupled to the other serially coupled amplifier inductor 124 through capacitor(s) in parallel with cascode BJT 122. During operation, load 120 in the form of an LNA circuit amplifies the amplitude of input signal RFin using the voltage applied at biasing terminal Vbias and the supply voltage transmitted from positive supply rail VDD. Structure 100 prevents RFin from undesirably passing into current generator 110 (e.g., due to the presence of OTA 102). Structure 100 reduces the amount of voltage needed for producing bias voltage at biasing terminal Vbias, e.g., by first transistor 104 being coupled to output terminal (Out) from OTA 102 to limit the magnitude of current generated in current generator 110.

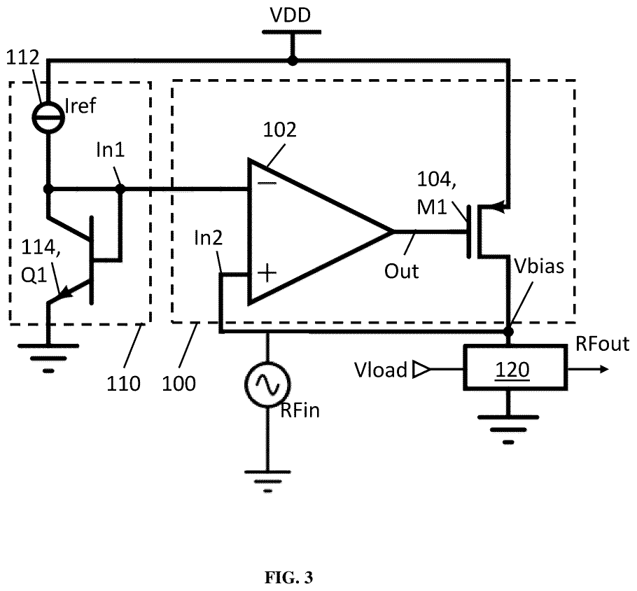

Referring briefly to FIG. 3, a schematic diagram of an equivalent circuit incorporating structure 100, current generator 110, and load 120 is shown to emphasize that load 120 may take variety of forms other than the LNA configuration shown in FIG. 2. In various implementations, load 120 may be any currently known or later developed amplifier and/or other types of electric circuits configured to receive a voltage bias at biasing terminal Vbias. In this case, load 120 is shown as being coupled to a load voltage (“Vload”) indicating positive voltage supply rail VDD and/or any other desired voltage input. Another input terminal to load 120 is coupled to biasing terminal Vbias of structure 100 to receive the biasing voltage produced by current generator 110, and further processed in structure 100. Load 120 thus may produce an output signal (RFout) based on the biasing voltage and incoming input signals (RFin) applied to structure 100. In further implementations, load 120 may be one of several electrical loads each configured to receive a biasing voltage at respective terminals.

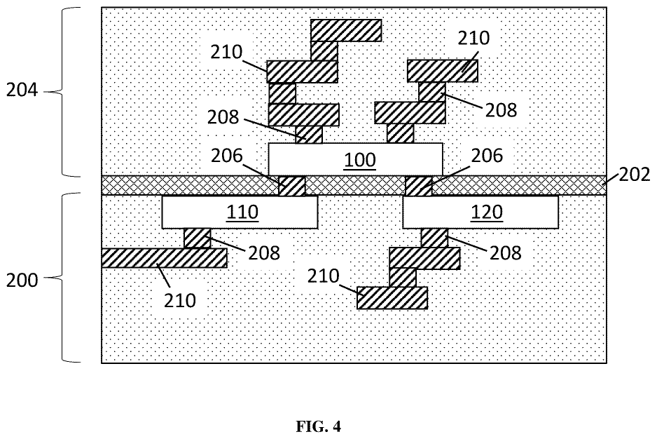

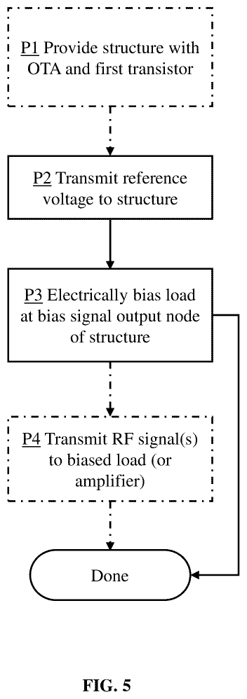

Referring to FIGS. 3 and 4, it is again noted that structure 100 may be implemented with a different type of transistor than those used in current generator 110 and/or load 120. For example, as described herein, first transistor 104 may be a FET (such as a PFET) whereas second transistor 114 may be a BJT (such as an NPN device). Optionally, these different transistor types may be manufactured and/or configured to operate together on one semiconductor substrate. In other implementations, however, each type of transistor may be formed on a different semiconductor substrate and interconnected with each other through a bonding interface between two different integrated circuit (IC) modules. FIG. 4 in particular depicts a first IC module 200 having a surface with a bonding interface 202 thereon. Bonding interface 202 may be include a layer of adhesive and/or insulative materials for bonding respective areas of insulative material together. Bonding interface 202, further, may include conductive couplings 206, which correspondingly integrate metal-to-metal bonding interfaces formed adjacent any bonding interfaces between insulative materials. In this case, conductive couplings 206 and bonding interface 202 together define a “hybrid bond” between materials with different properties. A second IC module 204 may be coupled to first IC module 200 along bonding interface 202 to enable each IC module 200, 204 to be electrically connected to each other.

First IC module 200 may include certain components shown in FIG. 3 and discussed herein, e.g., current generator 110 and load 120 may be located in respective portions of a device layer and/or other portion of first IC module 200. Current generator 110 and load 120 may be connected to each other and/or to other components within first IC module 200 through a set of vertical wires (also known as “vias” to indicate “vertical interconnect access”) 208 and metal level wires 210 extending horizontally through first IC module 200. Vertical wires 208 and metal level wires 210 may extend horizontally into and/or out of the plane of the cross-section shown in FIG. 4. Conductive couplings 206 within bonding interface 202, in addition, may define electrical pathways between structure 100 within second IC module 204 and current generator 110 and load 120 within first IC module 200. Structure 100, in turn, also can be electrically coupled to other components within second IC module 204 (and/or other components within first IC module 200 or other structures) through a corresponding set of vertical wires 208 and metal level wires 210. It is also understood that, where desired, any of structure 100, current generator 110, and/or load 120 may be located in the opposite IC module from its position in FIG. 4. In another example, any of strucutre100, current generator 110, and/or load 120 may be in a completely different IC module coupled to first IC module 200 and/or second IC module 204.

Referring now to FIGS. 2, 3, and 5 together, embodiments of the disclosure may include methods of operating structure 100 to electrically bias load(s) 120 connected thereto. FIG. 5 in particular provides an illustrative flow diagram for implementing methods according to the disclosure, and the various example processes P1-P4 shown therein may be implemented using embodiments of structure 100 shown in FIG. 2, FIG. 3, and/or any other conceivable implementation.

A preliminary operation (shown in dashed lines), process P1, may include providing structure 100 with OTA 102 and first transistor104 therein. Process P1 thus may entail, e.g., manufacturing structure 100 in a structure such as any of IC modules 200, 204 (FIG. 4), receiving structure 100 from a library of devices, modifying an existing product to include structure 100, and/or any other conceivable operation to yield structure 100 on a product and in an operative state. Process P1 thus also may include coupling structure 100 to positive voltage supply rail VDD and to each of current generator 110 and load 120, e.g., by connecting structure 100 to other portions of a device. In yet another example, process P1 may include coupling first and/or second IC module 204 with structure 100 therein to another IC module (e.g., first IC module 200) with current generator and/or load 120 therein. Process P1 is shown in dashed lines to indicate that it may be a preliminary operation, and thus omitted or undertaken separately in certain implementations.

Process P2 may include, e.g., transmitting a reference voltage from current generator 110 to structure 100 via OTA 102. Process P2 thus may include, e.g., transmitting a voltage from positive voltage supply rail VDD to reference current source 112. The electrical coupling from reference current source 112 to first input terminal In1 of OTA 102 (e.g., through second transistor 114 in a diode-connected configuration) may cause second input terminal In2 of OTA 102 to exhibit substantially the same voltage as first input terminal In2. In addition, first transistor 104 coupled to the output terminal (Out) from OTA 102 will limit the resulting current at input terminal In2 and biasing terminal Vbias connected thereto. Thus, operating current generator 110 by transmitting a reference current from reference current source 112 sets biasing terminal Vbias to a predetermined voltage level.

Continuing to process P3, methods of the disclosure may include electrically biasing load 120 using the voltage produced in structure 100 at biasing terminal Vbias. The biasing in process P3 may include, e.g., transmitting the voltage a biasing terminal Vbias to a biasing terminal within a particular device within load 120. More specifically, process P3 may include electrically biasing an LNA circuit (e.g., as shown in FIG. 2) using the voltage produced at biasing terminal Vbias during process P2. During operation, OTA 102 in structure 100 maintains a desired biasing voltage at biasing terminal Vbias. Structure 100, particularly first transistor 104 thereof, prevents any ensuring current this biasing voltage from being transmitted to current generator 110. First transistor 104, simultaneously, limits the resulting voltage at biasing terminal Vbias within desired limits and reduces the amount of voltage required to sustain the biasing voltage a biasing terminal Vbias.

The method may conclude (“Done”) after implementing process P3, e.g., when any further need to operate and electrically bias load 120 concludes. In further implementations, e.g., where load 120 includes an LNA circuit and/or other signal amplifier, embodiments of the disclosure may include process P4 of transmitting RF signal(s) to load 120. Process P4 may include transmitting an input signal (RFin) to structure 100 at second input terminal In2, such that the input signal is transmitted to load 120 with the biasing voltage from OTA 102. Thus, structure 100 is operable to transmit signals for amplification and to electrically bias the transmitted signals to enable desired amounts of amplification. In settings that do not include amplification and/or signal transmission, process P4 may be omitted.

Embodiments of the disclosure provide various technical and commercial advantages, examples of which are discussed herein. Embodiments of structure 100 may incur little to no use of additional surface area compared to conventional biasing circuits, e.g., due to the use of only first transistor 104 (e.g., a p-type field effect transistor (p-FET)) and OTA 102 (e.g., any currently known or later developed transimpedance amplifier configuration) in connection with current generator 110 and load 120. The operational characteristics of structure 100 discussed herein, in addition, reduce or prevent negative effects that would occur from passage of RF signals and/or biasing voltages into current generator 110, and/or similarly negative effects that would occur from excessive voltages at biasing terminal Vbias. Structure 100 may be integrated easily into conventional processing techniques, particularly where first transistor 104 is implemented using a FET architecture. In addition, structure 100 optionally may be implemented on a separate IC module from other device components (see, e.g., FIG. 4) yet may remain compatible for use with such components through hybrid bonding and/or similar techniques to connect different IC modules.

In the method and structures described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

The terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
an operational transconductance amplifier (OTA) including:
a first input terminal connected to a reference signal output node configured to receive a reference voltage,
a second input terminal connected to a bias signal output node configured to receive a bias voltage, and
an output terminal; and
a first transistor connected between a positive supply voltage rail and the bias signal output node, wherein a first control terminal of the first transistor is connected to the output terminal of the OTA.

2. The structure of claim 1, further comprising:
a reference current source and a second transistor connected in series between the positive supply voltage rail and ground, wherein the reference signal output node is at a junction between the reference current source and the second transistor.

3. The structure of claim 2, wherein the second transistor has a second control terminal connected to the reference signal output node.

4. The structure of claim 2, wherein the second transistor and the first transistor are different types of transistors.

5. The structure of claim 2, wherein the first transistor includes a field effect transistor having a gate connected to the output terminal of the OTA and the second transistor includes a bipolar junction transistor having a base connected to the reference signal output node.

6. The structure of claim 2, wherein the first transistor includes a P-type field effect transistor having a gate connected to the output terminal of the OTA and the second transistor includes an NPN-type bipolar junction transistor having a base connected to the first input terminal.

7. The structure of claim 1, wherein the first input terminal is an inverting input terminal and the second input terminal is a non-inverting input terminal.

8. The structure of claim 1, wherein the bias signal output node is connected to a load and an input signal.

9. The structure of claim 8, wherein the load is a low noise amplifier (LNA) circuit.

10. A structure comprising:
an operational transconductance amplifier (OTA) including:
a first input terminal connected to a reference signal output node to receive a reference voltage, and
a second input terminal connected to a bias signal output node to receive a bias voltage, and
an output terminal;
a first transistor connected between a positive supply voltage rail and the bias signal output node, wherein a first control terminal of the first transistor is connected to the output terminal of the OTA, and the bias signal output node is connected to an input signal;
a reference current source and a second transistor connected in series between the positive supply voltage rail and ground, wherein the reference signal output node is at a junction between the reference current source and the second transistor; and
a low noise amplifier (LNA) coupled to the bias signal output node.

11. The structure of claim 10, wherein the second transistor and the first transistor are different types of transistors.

12. The structure of claim 10, wherein the second transistor has a second control terminal connected to the reference signal output node.

13. The structure of claim 10, wherein the first transistor includes a field effect transistor having a gate connected to the output terminal of the OTA and the second transistor includes a bipolar junction transistor having a base connected to the reference signal output node.

14. The structure of claim 10, wherein the first transistor includes a P-type field effect transistor having a gate connected to the output terminal of the OTA and the second transistor includes an NPN-type bipolar junction transistor having a base connected to the reference signal output node.

15. The structure of claim 10, wherein the OTA is on a first integrated circuit (IC) module, and the reference current source and the LNA are on a second IC module coupled to the first IC module.

16. A method comprising:
transmitting a reference voltage to a structure including:
an operational transconductance amplifier (OTA) including:
a first input terminal connected to a reference signal output node to receive the reference voltage, and
a second input terminal connected to a bias signal output node to receive a bias voltage; and an output terminal, and
a first transistor connected between a positive supply voltage rail and the bias signal output node, wherein a first control terminal of the first transistor is connected to the output terminal of the OTA; and
electrically biasing a load coupled to the bias signal output node with the bias voltage.

17. The method of claim 16, wherein the structure further includes a reference current source and a second transistor connected in series between the positive supply voltage rail and ground, wherein the reference signal output node is at a junction between the reference current source and the second transistor.

18. The method of claim 17, wherein the first transistor includes a field effect transistor having a gate connected to the output terminal of the OTA and the second transistor includes a bipolar junction transistor having a base connected to the reference signal output node.

19. The method of claim 17, wherein the first transistor includes a P-type field effect transistor having a gate connected to the output terminal of the OTA and the second transistor includes an NPN-type bipolar junction transistor having a base connected to the reference signal output node.

20. The method of claim 16, wherein the load is a low noise amplifier (LNA) circuit.
